(19) United States
(12) Patent Application Publication
(10) Pub. No.: US 2003/0148630 A1
(43) Pub. Date: Aug. 7, 2003

(54) Self-grown hydrophobic nano molecule organic diffusion barrier and method of the same

(75) Inventor: Jung-Chih Hu, Kaohsiung (TW)

Correspondence Address: MERCHANT & GOULD PC, P.O. BOX 2903, MINNEAPOLIS, MN, 55402-0903, US

(73) Assignee: United Microelectronics Corp., Hsin-Chu City (TW)

(21) Appl. No.: 10/368,911

(22) Filed: Feb. 14, 2003

Related U.S. Application Data
(62) Division of application No. 10/056,198, filed on Jan. 23, 2002.

(51) Int. Cl. H01L 21/31; H01L 21/469

(52) U.S. Cl. 438/781

(57) ABSTRACT

A structure of a hydrophobic nano organic molecular diffusion barrier on dielectric material and the method for fabricating said hydrophobic nano organic molecular diffusion barrier is disclosed. This invention provides a method for fabricating a hydrophobic nano organic molecular diffusion barrier on dielectric material after plasma dry-etching or chemical mechanical polishing. The hydrophobic nano organic molecular diffusion barrier can spontaneously generate a hydrophobic organic barrier film to prevent from the moisture absorption of the dielectric material, and the thickness of the hydrophobic organic barrier film is equal in nano scale. Moreover, said hydrophobic nano organic molecular diffusion barrier can successfully keep Cu atoms from the dielectric material. Therefore, it is able to be efficient in resolving the problems of moisture absorption and Cu atom diffusion of the dielectric material by the nano molecular organic diffusion barriers according to this invention.

### BACKGROUND OF THE INVENTION

1. Field of the Invention

This present invention relates to an organic diffusion barrier, and more particularly to a self-grown hydrophobic nano molecule organic diffusion barrier formed onto dielectric material and method of the same.

2. Description of the Prior Art

In ultra large-scale integration (ULSI), noise between interconnects, attributed to decreasing line width, leads to RC delay of resistances. Presently, advanced Cu metallization process has been successfully introduced into semiconductor manufactures, and replaced conventional aluminum (Al) with high resistivity and low resistance of electromigration. Additionally, utilizing low-k dielectric materials (materials with low dielectric constant) to displace traditional dielectric materials, as SiO₂ and FSG (fluorinated SiO₂), is useful for decreasing the delay of capacitors. Recently, porous low-k SiO₂ film, such as porous hydrogen silsesquioxane (PHSQ) and porous methyl silsesquioxane (PMSQ), is developed and noted by its dielectric constant lower than 2. Moreover, according to the decreasing line width, the thickness of metal diffusion barriers, such as Ta, TaN, TaSiN, WN, etc., between Cu metal and dielectric materials will be decreased along with the devices scale. As a result, the diffusion probability of Cu atoms through the metal diffusion barrier and enter the dielectric material will be increased. Thus, the decreasing of the thickness of metal diffusion barrier will lead to the increase of current leakage of devices.

The problem of moisture absorption of dielectric materials as-deposited by the standard process is not serious. However, after plasma dry-etching or chemical mechanical polishing in semiconductor manufacturing, lots of hydroxy groups (Si—OH) are generated on the dielectric materials, particularly on low-k dielectric materials. The hydroxy groups are dangling bonds. The hydroxy groups of the dielectric materials can trap water molecular by hydrogen bonding force between the hydroxy groups and water molecular. The hydrogen bonding force raises the problem of moisture absorption of the dielectric materials. The problem of moisture absorption is particularly acute in porous low-k dielectric materials. The moisture absorption will appear on the surface and a partial side portion of the dielectric materials. The moisture absorption of the dielectric materials is not only increasing the dielectric constant of the dielectric materials, but also raising difficulty of the adhesion while metal barriers are deposited onto the dielectric materials.

Therefore, it is necessary to develop a barrier film to prevent from the moisture absorption of dielectric materials after plasma dry-etching or chemical mechanical polishing treatment, and to keep the Cu atoms from diffusing into the dielectric materials.

### SUMMARY OF THE INVENTION

In accordance with the present invention, a method is provided for fabricating an organic diffusion barrier on dielectric material to form a hydrophobic organic molecular protective film onto the dielectric material.

It is another object of this invention to form an organic diffusion barrier on a dielectric material to keep Cu atoms from diffusing into the dielectric material.

Still another object of this invention is to form an organic diffusion barrier on a dielectric material to reduce current leakage.

Still another object of this invention is to form a hydrophobic organic diffusion barrier on a dielectric material to prevent from moisture absorption of the dielectric material.

Still another object of this invention is to form an organic diffusion barrier on dielectric material to avoid the difficulty of adhesion while a metal barrier is deposited onto the dielectric material.

Still another object of this invention is to form an organic diffusion barrier on a dielectric material wherein the organic diffusion barrier is as thick as nano scale.

In accordance with the above-mentioned objects, the invention provides a method for fabricating an organic diffusion barrier on dielectric material after plasma dry-etching or chemical mechanical polishing. The organic diffusion barrier can spontaneously form a hydrophobic organic molecular protective film, and the thickness of the hydrophobic organic protective film is equal to nano scale. Moreover, the organic diffusion barrier can successfully keep Cu atoms from diffusing into the dielectric material. Therefore, it is efficient for fabricating nano molecular organic diffusion barriers on dielectric materials to prevent from moisture absorption and Cu atoms diffusion of dielectric materials by the method.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a diagram showing a dielectric material after plasma dry-etching or chemical mechanical polishing;

FIG. 2 is a schematic representation showing the formation of a hydrophobic organic molecular protective film of the dielectric material after reaction with ATPMS; and

FIG. 3 is a schematic representation showing how the hydrophobic organic molecular protective film keeps metal atoms from diffusing into the dielectric material.

### DESCRIPTION OF THE PREFERRED EMBODIMENTS

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

Then, the components of the semiconductor devices are not shown to scale. Some dimensions are exaggerated to the related components to provide a more clear description and comprehension of the present invention.

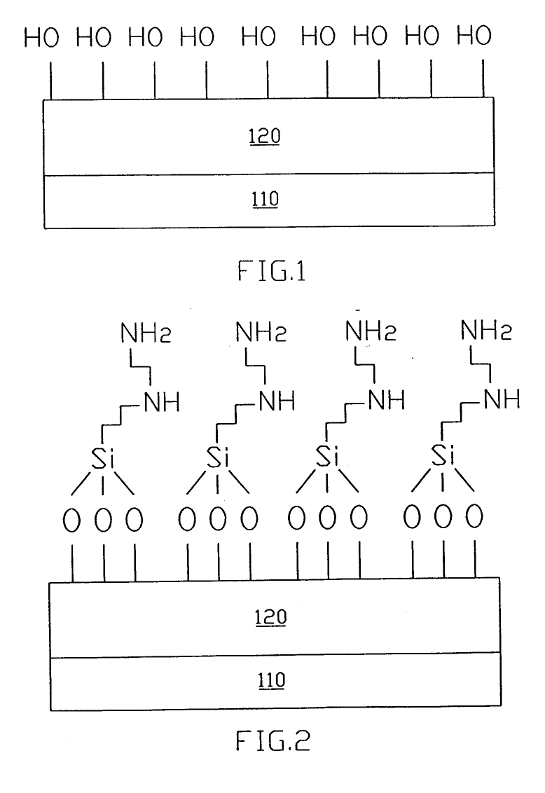

Referred to drawings, one preferred embodiment of this invention is a method for forming a nano molecular organic diffusion barrier on a dielectric material. Referred to FIG. 1 now, a wafer comprises a substrate 110 and a dielectric layer 120. The dielectric layer 120 is made of a low-k dielectric material, such as traditional SiO₂, fluorinated SiO₂ (FSG), silsesquioxane (HSQ), and methyl silsesquioxane (MSQ), and porous low-k dielectric material, such as porous methylsilsesquioxane (PMSQ), and so on. After plasma dry-etching or chemical mechanical polishing process, dangling bonds of Si of the dielectric layer 120 are generated on the surface of the dielectric layer 120, and thus a plurality of hydrophilic hydroxy groups (Si—OH) are produced. The hydroxy groups of the dielectric layer 120 will lead to the problem of moisture absorption in prior art.

After the process of plasma dry-etching or chemical mechanical polishing, the wafer is dipped into a solution of 3-(2-aminoethylamino) propyltrimethoxysilane (ATPMS; an available chemical reagent) for 5-20 min. to form the desired nano organic molecular diffusion barrier, wherein the concentration of the solution of ATPMS is 0.5 to 3.0 mM. The reaction between the wafer and ATPMS is performed by simply dipping, or supersonic and/or refluxing. During the reaction, inorganic acid, such as sulfuric acid, hydrochloric acid, or nitric acid, is added to accelerate rate of the reaction.

Subsequently, methanol (CH₃OH) or acetone (C₃H₆O), and deionized water are utilized for washing the wafer. After washing, the wafer is dried by nitrogen purging, and incurs a baking process in a nitrogen oven at 200-300° C. for 10-20 min. The baking process is employed to drive the reaction between the wafer and ATPMS completely. After the nano organic molecular diffusion barrier is formed, neutro-water (H₂O), as the side product in the reaction between the hydrophilic hydroxy groups and ATPMS, will be removed by the baking process. FIG. 2 is a schematic representation showing the formation of a nano organic molecular diffusion barrier in accordance with a method disclosed herein.

The dangling bonds and the hydroxy groups of the dielectric layer 120 after plasma dry-etching or chemical mechanical polishing process is hydrophilic by the hydrogen bonding effect between the hydroxy group and water molecule. However, after reaction with ATPMS in accordance with the above-mentioned method, the hydroxy groups (Si—OH) are blocked and replaced by a hydrophobic organic protective barrier (Si—O—Si(CH₃)₃NH(CH₂)₂NH₂). Consequently, the nano organic molecular diffusion barrier spontaneously becomes a hydrophobic organic barrier film, and the hydrophobic organic barrier film is efficient in preventing from moisture absorption of the low-k dielectric material.

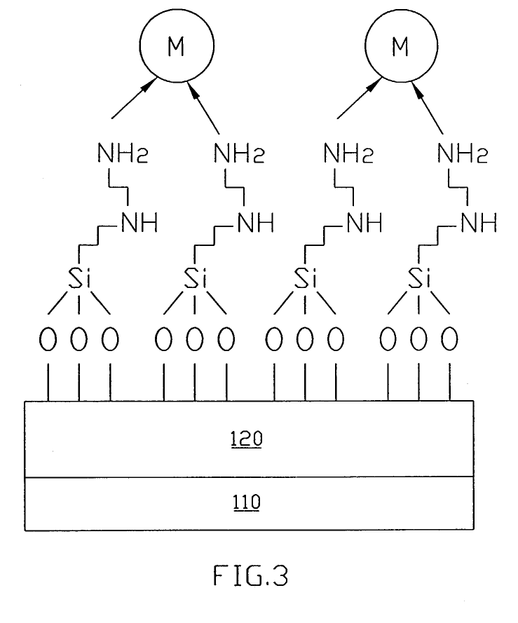

Another character of the nano organic molecular diffusion barrier according to this invention is keeping metal atoms, like Cu, Ag, or Au atoms, from diffusing into the dielectric material. While the thickness of metal diffusion barriers are decreased with the scale of device, the diffusion probability of metal atoms into the dielectric material is increasing. The metal diffusion barrier, consisted of Ta, TaN, TaSiN, WN, and so on, is formed on the dielectric layer 120, not shown in the drawings. In said preferred embodiment, when metal atoms, such as Cu atoms, diffuse through the metal diffusion barrier, the nano organic molecular diffusion barrier according to this invention will efficiently trap the metal atoms. The lone pair electrons of the p orbital of the N atoms of the amino groups of ATPMS can form p-d π bonding with the d orbital of Cu atoms, and thus the nano organic molecular diffusion barrier can successfully keep Cu atoms from diffusing into the dielectric layer 120, and thus the current leakage of the wafer can be decreased, as shown in FIG. 3.

Additionally, the thickness of the nano organic molecular diffusion barrier on the dielectric layer 120 is from 20 to 30 angstroms, i.e., the thickness of the organic barrier film formed on the dielectric layer 120 is in nano scale. Thus the nano molecular organic diffusion barrier film according to this invention is as thick as zero-thickness and suitable to the decreasing scale of devices.

It is notably such that this invention is not limited by said preferred embodiment. For example, the reagent utilized in this invention has a general formula (R′O)₃Si(CH₂)₃[(NH)(CH₂)₂]ₓNH₂, wherein R′O can be an alkoxy group, and x is an integer from 0 to 4. After the reaction between the reagent and the dielectric material comprising Si atoms, there is a structure with a formula of (RO)₃Si(CH₂)₃[(NH)(CH₂)₂]ₓNH₂ formed on the dielectric material, wherein R is the Si atom of the dielectric material, and x is an integer from 0 to 4.

Preferably, all of the manufacture of the nano organic molecular diffusion barrier is simplified, and complex photolithography process is useless in the manufacture.

According to the preferred embodiment, this invention discloses a method to fabricate a hydrophobic nano molecular organic diffusion barrier. This invention can prevent moisture absorption of dielectric materials by forming a hydrophobic organic barrier film on the dielectric materials. Moreover, in this invention, it is possible to avoid the diffusion of metal atoms, such as Cu atoms, into the dielectric materials by trapping the metal atoms with the amino groups of the hydrophobic nano organic molecular diffusion barrier. Thus, the method of this present invention can prevent the moisture absorption and improve the current leakage of the dielectric materials.

Although specific embodiments have been illustrated and described, it will be obvious to those skilled in the art that various modifications may be made without departing from what is intended to be limited solely by the appended claims.

What is claimed is:

1. A structure of a hydrophobic organic diffusion barrier on a dielectric material, comprising:
a chemical structure, wherein said chemical structure has a formula of (RO)₃Si(CH₂)₃[(NH)(CH₂)₂]ₓNH₂.

2. The structure according to claim 1, wherein said dielectric material comprises Si.

3. The structure according to claim 1, wherein R is Si of the dielectric material.

4. The structure according to claim 1, wherein x is an integer from 0 to 4.

5. The structure according to claim 1, wherein said chemical structure is formed from a reaction between the dielectric material and a chemical reagent with a formula of (R′O)₃Si(CH₂)₃[(NH)(CH₂)₂]ₓNH₂.

6. The structure according to claim 5, wherein said R′O is an alkoxy group.

7. The structure according to claim 2, wherein said dielectric material is a low-k dielectric material.

8. The structure according to claim 1, wherein said dielectric material is a porous low-k dielectric material.

9. A process for generating a hydrophobic organic diffusion barrier, wherein said process is ultilized in semiconductor manufacturing, comprising:
providing a dielectric material;
dipping the dielectric material into a solution of a reagent, wherein the reagent has a formula of (R′O)₃Si(CH₂)₃[(NH)(CH₂)₂]ₓNH₂;
washing the dielectric material with a solvent; and
baking the dielectric material.

10. The process according to claim 9, wherein said R′O of the formula is an alkoxy group, and said x of the formula is an integer from 0 to 4.

11. The process according to claim 9, wherein a chemical structure with a formula of (RO)₃Si(CH₂)₃[(NH)(CH₂)₂]ₓNH₂ is generated onto said dielectric material in said dipping step.

12. The structure according to claim 9, wherein said dielectric material comprises Si.

13. The process according to claim 12, wherein said R is Si of said dielectric material, and said x of the formula is an integer from 0 to 4.

14. The process according to claim 9, wherein supersonic is utilized in said dipping step.

15. The process according to claim 9, wherein refluxing is utilized in said dipping step.

16. The process according to claim 9, inorganic acid is utilized in said dipping step.

17. The process according to claim 9, wherein said dipping step is performed at 20-100° C. for 1-60 min.

18. The process according to claim 9, further comprising a step for purging nitrogen to the dielectric material after said dipping step.

19. The process according to claim 9, wherein said baking step is performed in a nitrogen oven at 100-400° C. for 1-60 min.

20. The process according to claim 9, wherein said solvent utilized in said washing step comprises an organic solvent.

21. The process according to claim 9, wherein said solvent utilized in said washing step comprises and deionized water.

22. The process according to claim 9, wherein said dielectric material is a low-k dielectric material.

23. The process according to claim 12, wherein said dielectric material is a low-k dielectric material.
